(19) United States
(12) Patent Application Publication
(10) Pub. No.: US 2002/0081872 A1
(43) Pub. Date: Jun. 27, 2002

(54) Electrical card connector

(76) Inventor: Hung-Chi Yu, Hsi-Chih (TW)

Correspondence Address: Wei Te (Joseph) Chung, Foxconn International, Inc., 1650 Memorex Drive, Santa Clara, CA, 95050, US

(21) Appl. No.: 09/803,483

(22) Filed: Mar. 8, 2001

(30) Foreign Application Priority Data
Dec. 21, 2000 (TW) 89222260

(51) Int. Cl. H05K 1/00

(52) U.S. Cl. 439/79

(57) ABSTRACT

A PCMCIA card connector (1) includes a dielectric housing (20) and a number of first and second terminals (31, 32) received in the dielectric housing. The dielectric housing comprises a pair of parallel arms (200) and a main body (201) between the arms. The main body comprises a front mating face (25) and a bottom face (26). Each of the terminals defines a horizontal contact portion (31a, 32a), a solder portion (31b, 32b) and a vertical mounting portion (31c, 32c). The solder portion extends downwardly from the contact portion for soldering to a printed circuit board. The mounting portion of the first terminal extends downwardly from the contact portion and the mounting portion of the second terminal extends upwardly from the contact portion. The mounting portions are received in mounting holes (22, 24) of the dielectric housing from a top and a bottom sides of the dielectric housing.

### BACKGROUND OF THE INVENTION

1. Field of the Invention

The present invention relates to an electrical card connector, and particularly to an electrical card connector which has a reduced front-to-rear length.

2. Description of Related Art

As the popularity of notebook computers increases, integrated circuit (IC) cards are becoming more common for increasing storage capacity or interfacing the notebook computers with other devices. Card connectors are commonly used to connect mother boards of the computer with the cards. Most current IC cards and card connectors conform to the standards of Personal Computer Memory Card International Association (PCMCIA).

Conventional PCMCIA card connectors are disclosed in U.S. Pat. No. 5,601,438 and Taiwan Patent Application Nos. 84206174 and 84206175. Referring to FIG. 4, a conventional PCMCIA card connector 7 comprises a dielectric housing 71 and a plurality of terminals 72, 73. The dielectric housing 71 defines a plurality of receiving passageways 711, 712 extending through the housing 71 from a front face 713 to a rear face 714 thereof in upper and lower rows. Each terminal 72 (73) comprises a contact portion 72b (73b) at one end thereof, a solder portion 72c (73c) at the other end thereof, and a fixing portion 72a (73a) between the contact portion 72b (73b) and the solder portion 72c (72c). The terminals 72, 73 are assembled in corresponding receiving passageways 711, 712 of the housing 71 with the contact portions 72b, 73b extending beyond the front face 713, the fixing portions 72a, 73a secured in the receiving passageways 711, 712, and the solder portions 72c, 73c soldered to a printed circuit board 8. Because the solder portions 72c, 73c of the terminals 72, 73 are all located at a rear side of the housing 71 and in particular the solder portions 72c are located farther from the rear face 714 of the housing 71 than the solder portions 73c, the whole length of the PCMCIA card connector 7 is increased, thereby occupying increased space on the printed circuit board 8.

Hence, an improved PCMCIA card connector is required to overcome the disadvantages of the conventional electrical card connector.

### SUMMARY OF THE INVENTION

Accordingly, a main object of the present invention is to provide a PCMCIA card connector having a reduced length thereby occupying less space on a printed circuit board.

In order to achieve the object set forth, a PCMCIA card connector in accordance with the present invention includes a dielectric housing and a plurality of first and second terminals received in the dielectric housing. The dielectric housing includes a pair of parallel arms and a main body between the arms. The main body comprises a frontmating face, a rear face opposite to the front mating face, a bottom face, and an upper face opposite to the bottom face. The main body defines a plurality of vertical mounting holes on the upper face and bottom face. The first and second terminals are inserted into the main body from upper and lower faces thereof, respectively. Each terminal defines a horizontal contact portion, a solder portion and a vertical mounting portion. The contact portion extends beyond the mating face for mating with the electrical card. The solder portion of the first terminal extends downwardly from rear end of the contact portion and a horizontal portion thereof extends rearwardly beyond the rear face of the housing. The solder portion of the second terminal extends from a middle of the contact portion and a horizontal portion thereof extends forwardly beyond the mating face. The mounting portion of the first terminal extends downwardly from a middle of the contact portion of the first terminal. The mounting portion of the second terminal extends upwardly from a rear end of the contact portion of the second terminal. The mounting portions are received in the vertical mounting holes thereby securing the terminals to the dielectric housing

Other objects, advantages and novel features of the invention will become more apparent from the following detail description when taken in conjunction with the accompanying drawings.

### BRIEF DESCRIPTION OF THE DRAWINGS

FIG. 1 is an exploded, perspective view of a PCMCIA card connector in accordance with the present invention and a printed circuit board;

FIG. 2 is a partial, cross-sectional view of a dielectric housing of the PCMCIA card connector of FIG. 1;

FIG. 3 is a cross-sectional view of the PCMCIA card connector mounted on the printed circuit board; and

FIG. 4 is a cross-sectional view of a conventional PCMCIA card connector which is mounted on the printed circuit board.

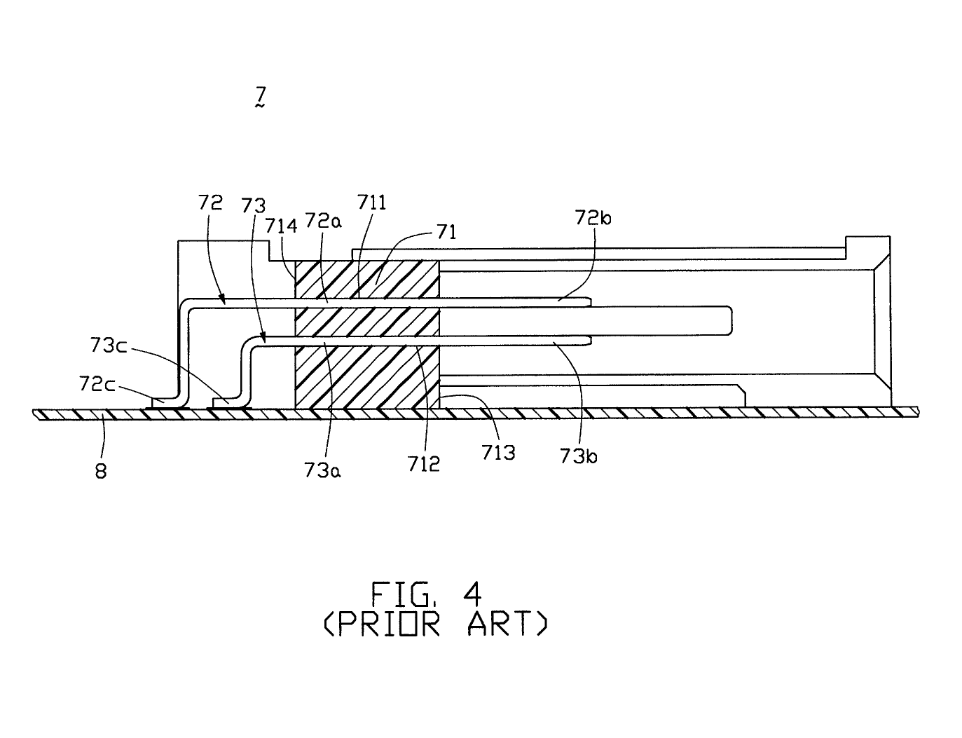

### DETAILED DESCRIPTION OF THE INVENTION

Reference will now be made to the drawing figures to describe the present invention in detail.

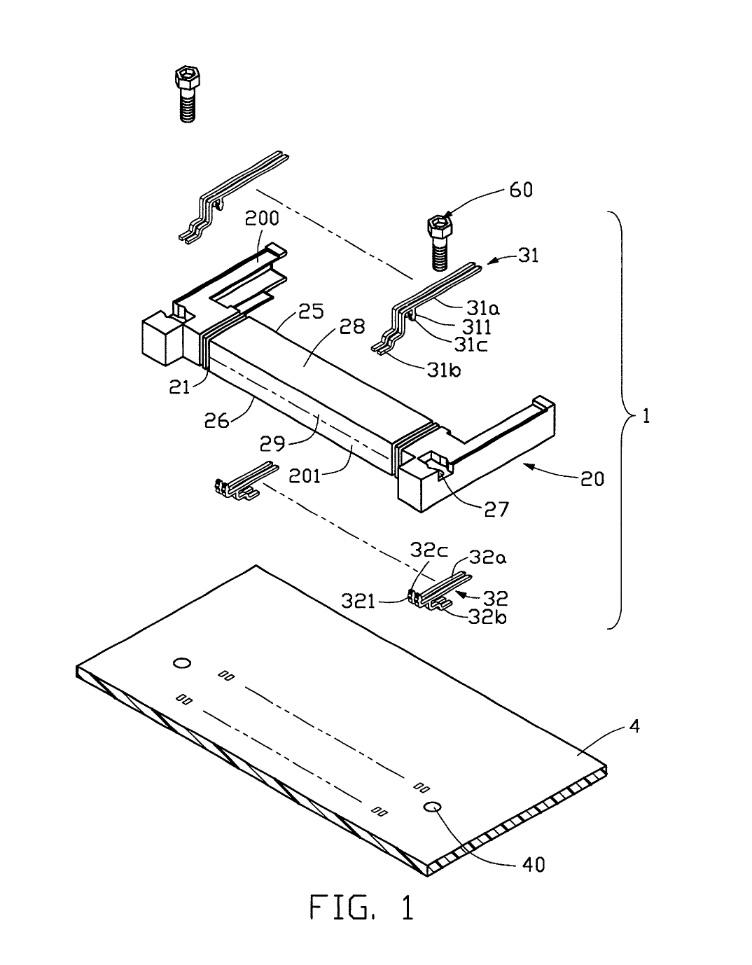

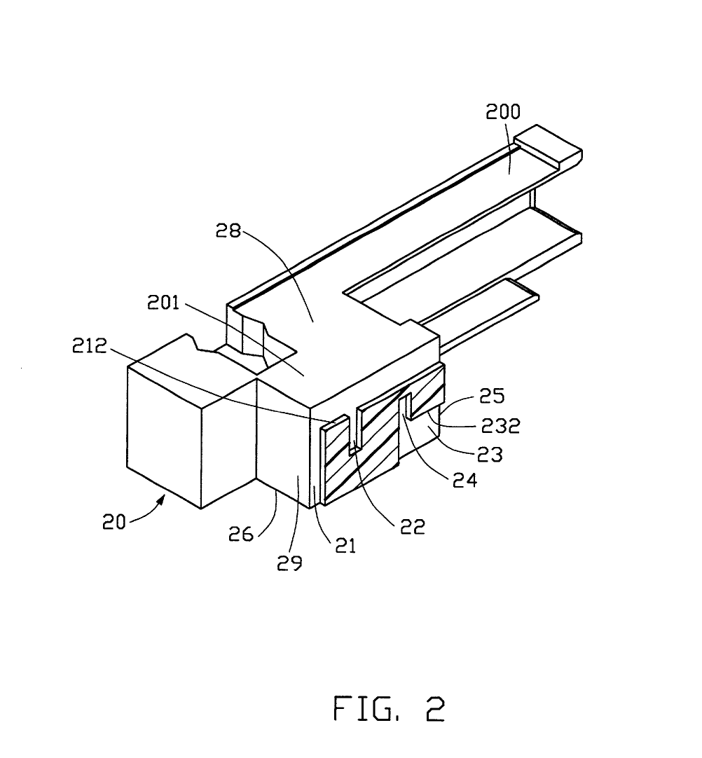

Referring to FIG. 1 and FIG. 2, a PCMCIA card connector 1 in accordance with the present invention includes a dielectric housing 20, a plurality of first terminals 31 and second terminals 32, and a pair of fasteners such as screws 60.

The dielectric housing 20 comprises a pair of parallel arms 200 and a main body 201 between the arms 200. The main body 201 comprises a front mating face 25, a rear face 29 opposite to the front mating face 25, a bottom face 26, and an upper face 28 opposite to the bottom face 26. The main body 201 defines a plurality of L-shaped first receiving channels 21 exposed to the upper face 28 and the rear face 29 thereof, and a plurality of horizontal second receiving channels 23 in the bottom face 26 thereof. Each of the first and second receiving channels 21, 23 respectively has a first and second bottom face 212, 232. The main body 201 further defines an upper vertical mounting hole 22 in the first bottom face 212 to communicate with the first receiving channel 21, and a lower vertical mounting hole 24 in the second bottom face 232 to communicate with the horizontal second receiving channel 23. Each upper vertical mounting hole 22 aligns wth each lower vertical mounting hole 24 along the direction that the arms 200 extend. The arms 200 each defines a retention hole 27 near the main body 201 for extension of the screw 60 to fix the connector 1 to the printed circuit board 4.

The first and second terminals 31, 32 respectively comprise horizontal contact portions 31a, 32a. A solder portion 31b extends downwardly and rearwardly from a rear end of the contact portion 31a of the first terminal 31 and a solder portion 32b extends downwardly and forwardly from a middle portion of the contact portion 32a of the second terminal 32. Each first terminal 31 comprises a mounting portion 31c extending downwardly and vertically from a middle portion of the contact portion 31a. Each second terminal 32 includes a mounting portion 32c extending upwardly and vertically from a rear end of the contact portion 32a. The mounting portions 31c, 32c form protrusions 311, 321 for biting the housing 20.

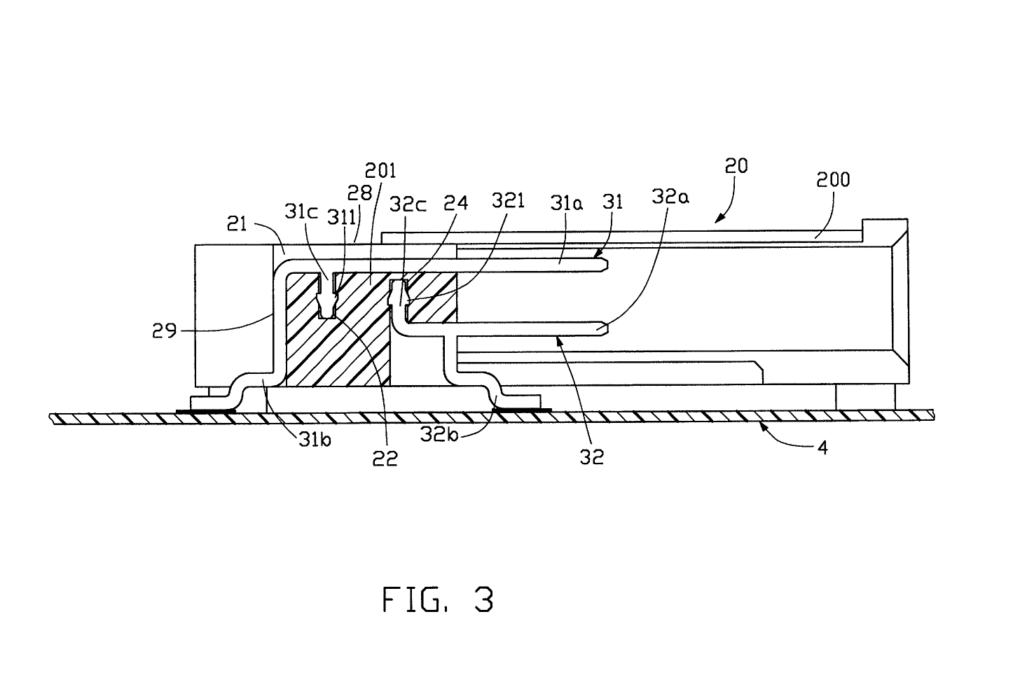

Referring to FIG. 2 and FIG. 3, in assembly, the first terminals 31 are inserted into the main body 201 from an upper side thereof to a position wherein the mounting portions 31c are received in the mounting holes 22 in which the protrusions 311 bite into the housing 20 to secure the first terminals 31 to the housing 20, and the contact portions 31a are received in a horizontal section of the first receiving channels 21 with a mating portion thereof protruding forwardly beyond the mating face 25 of the main body 201 for mating with an inserted electrical card (not shown). A vertical section of each solder portion 31b is fitted in a vertical section of the corresponding first receiving channel 21 while a lower horizontal section of the solder portion 31b horizontally and rearwardly extends from a lower end of the vertical section of the solder portion 31b. The second terminals 32 are inserted into the main body 201 from a lower side thereof to a position where the mounting portions 32c are received in the mounting holes 24 with the protrusions 321 biting into the housing 20 thereby securing the second terminals 32 to the housing 20. The contact portions 32a are received in the corresponding second receiving channels 23 with a mating portion thereof protruding forwardly beyond the mating face 25 of the main body 201 for mating with the electrical card. A vertical section of each solder portion 32b is fitted in a corresponding second receiving channel 23 while a lower horizontal section of the solder portion 32b horizontally and forwardly extends from a lower end of the vertical section of the solder portion 32b. The screws 60 extend through the retention holes 27 of the housing 20 and through holes 40 of the printed circuit board 4 to mount the housing 20 on the printed circuit board 4. Finally, the horizontal sections of the solder portions 31b, 32b are soldered to the printed circuit board 4.

The terminals 31, 32 are inserted into the main body 201 from two opposite sides and the solder portions 31b, 32b are located on different sides of the main body 201. Therefore, the length of the PCMCIA card connector 1 can be reduced, thereby occupying less area on the printed circuit board 4. In addition, the mounting portions 31c, 32c are vertically inserted into the mounting holes 22, 24, while the force of he terminals 31, 32 being subjected to is horizontal, so the terminals 31, 32 can not be pushed or pulled out of the main body 201 during mating with the electrical card. Therefore, the terminals 31, 32 are securely mounted to the dielectric housing 20.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electrical card connector adapted for interconnecting an electrical card with a printed circuit board, comprising:
a dielectric housing comprising a front mating face and a plurality of upper and lower vertical mounting holes;
a plurality of first terminals each having a contact portion extending forwardly beyond the mating face for engaging with an electrical card and a first vertical mounting portion extending downwardly from the contact portion, the first vertical mounting portion being secured in the upper vertical mounting hole of the dielectric housing; and
a plurality of second terminals each having a contact portion extending forwardly beyond the mating face for engaging with the electrical card and a second vertical mounting portion extending upwardly from the contact portion, the second vertical mounting portion being secured in the lower mounting hole of the dielectric housing.

2. The electrical card connector in accordance with claim 1, wherein the first and the second terminals each comprise a solder portion extending downwardly from the contact portion for soldering to a printed circuit board.

3. The electrical card connector in accordance with claim 2, wherein the dielectric housing defines a rear face opposite to the front mating face, a bottom face facing the printed circuit board, and a receiving channel in the rear face, and the solder portion of the first terminal comprises a vertical portion engaged with the channel.

4. The electrical card connector in accordance with claim 2, wherein the dielectric housing defines a bottom face facing the printed circuit board, and a receiving channel in the bottom face, and a section of the solder portion of the second terminal engages with the channel.

5. The electrical card connector in accordance with claim 1, wherein the dielectric housing comprises a main body and a pair of parallel arms at each end of the main body.

6. The electrical card connector in accordance with claim 1, wherein each of the mounting portions of the first and the second terminals forms a protrusion for interference fitting in a corresponding mounting hole.

7. An electrical header connector adapted for interconnecting an electrical card with a printed circuit board, comprising:
a dielectric housing comprising a front mating face, a rear face opposite to the front mating face, a bottom face facing a printed circuit board, and a plurality of upper and lower mounting holes perpendicular to the bottom face;
a plurality of first terminals, each terminal having a contact portion, a solder portion and a mounting portion, the contact portion extending forwardly beyond the mating face for mating with an electrical card, the solder portion extending out of the bottom face for soldering to the printed circuit board, the mounting portion extending downwardly from the contact portion and being received in the upper mounting hole for securing to the dielectric housing; and
a plurality of second terminals, each terminal having a contact portion, a solder portion and a mounting portion, the contact portion extending forwardly beyond the mating face for mating with an electrical card, the solder portion extending out of the bottom face for soldering to the printed circuit board, the mounting portion extending upwardly from the contact portion and being received in lower the mounting hole for securing to the dielectric housing.

8. An electrical connector comprising:
a dielectric housing comprising a front mating face defining a horizontal mating direction for use with a card, and a plurality of upper and lower receiving channels, said upper receiving channels being upwardly and rearwardly exposed to an exterior, and said lower receiving channels being forwardly and downwardly exposed to the exterior;
a plurality of upper terminals respectively disposed in said upper receiving channels, each of said upper terminals being downwardly installed into the housing; and
a plurality of lower terminals respectively disposed in said lower receiving channels, each of said lower terminals being upwardly installed into the housing.

9. The connector as claimed in claim 8, wherein both said upper terminal and said lower terminal include contact portions extending forwardly beyond the front mating face in a same direction, while the upper terminal defines a rearwardly extending solder portion and the lower terminal defines a forwardly extending solder portion in an opposite direction.
